(19) United States
(12) Patent Application Publication
(10) Pub. No.: US 2005/0012192 A1
(43) Pub. Date: Jan. 20, 2005

(54) Hybrid integrated circuit

(75) Inventor: Toru Saso, Kanagawa (JP)

Correspondence Address: Choate, Hall & Stewart;Patent Group, Exchange Place, 53 State Street, Boston, MA, 02109-2804, US

(73) Assignee: NEC Compound Semiconductor Devices, Ltd.

(21) Appl. No.: 10/864,259

(22) Filed: Jun. 9, 2004

(30) Foreign Application Priority Data
Jun. 30, 2003 (JP) 2003-186864

(51) Int. Cl. H01L 23/02

(52) U.S. Cl. 257/678

(57) ABSTRACT

The hybrid integrated circuit includes a first wiring substrate having a plurality of signal line layers and a plurality of ground conductive layers, each of the signal line layers and a corresponding one of the ground conductive layers making up a microstrip line; a cavity formed in the first wiring substrate to expose one of the ground conductive layers at a bottom of the cavity; a semiconductor chip mounted in the cavity and having a bottom surface fixed to the one of the ground conductive layers; and a mounting component mounted to an upper surface of the first wiring substrate but not above the cavity.

### BACKGROUND OF THE INVENTION

1. Field of the Invention

The present invention relates to a hybrid integrated circuit (HIC) and, more particularly, to a hybrid integrated circuit having high heat dissipation capability and electromagnetic field shielding capability while being compact.

2. Description of the Related Art

With miniaturization of mobile communication devices such as cellular phones, demand for miniaturization of electronic components and so on that constitute the mobile communication devices is increasing. A hybrid integrated circuit such as a high-frequency amplifier circuit used as a transmission part of the mobile communication device is one of major devices for the mobile communication devices. The hybrid integrated circuit, however, has a problem that its heat dissipation capability decreases as the device size decreases, which deteriorates the performance as a power amplifier. Thus, it is required to achieve the miniaturization of the hybrid integrated circuit while maintaining high heat dissipation capability.

A conventional hybrid integrated circuit using a flip-chip bonding of a bare chip of semiconductor is described in Japanese Unexamined Patent Application Publication 2002-184931 from the paragraph 0015 to 0019 and illustrated in FIG. 1. FIG. 6 is a cross-sectional view showing the structure of the hybrid integrated circuit (hybrid module component) according to this conventional technique.

The hybrid integrated circuit 30 in FIG. 6 comprises a wiring substrate 34 composed of a first dielectric layer 32 having a cavity 31 and a second dielectric layer 33 deposited on the first dielectric layer 32. A plurality of mounting components 35 are placed individually on the wiring substrate 34. The mounting components 35 are connected to line patterns (not shown) formed on the wiring substrate 34. A semiconductor chip 36 is placed in the cavity 31. The semiconductor chip 36 is flip-chip bonded to the under surface of the second dielectric layer 33 via an electrode (metal bump) 36a. The wiring substrate 34 and the mounting components 35 are entirely shielded by a metal case 37. A heat dissipation plate 38 is placed under the first dielectric layer 32 and connected to the under surface of the semiconductor chip 36 via a conductive resin 39. Another surface of the heat dissipation plate 38 is connected to a mother board, which is not shown in the figure.

The hybrid integrated circuit 30 achieves miniaturization by placing the semiconductor chip in the cavity 31, which has conventionally been placed on the surface of a dielectric substrate. Further, the hybrid integrated circuit 30 maintains high heat dissipation capability by dissipating the heat generated by the semiconductor chip 36 with a high heat value to the mother board or ambient air through the electrode 36a, the second dielectric layer 33, and the case 37, or to the mother board through the heat dissipation plate 38.

However, though the hybrid integrated circuit 30 has the structure to dissipate the heat generated by the semiconductor chip 36 through both the electrode 36a and the heat dissipation plate 38, a large portion of the heat from the semiconductor chip 36 is dissipated through the electrode 36a, which is electrically connected to the semiconductor chip 36.

In addition, since a distance to transfer the heat from the electrode 36a through the second dielectric layer 33 to the case 37 or mother board as heat dissipation media is very long, the heat dissipation capability is insufficient in the conventional hybrid integrated circuit 30. This can cause deterioration of the second dielectric layer 33 and the mounting components 35 due to the heat.

Besides the problem of heat dissipation structure, the conventional hybrid integrated circuits have a problem that miniaturization results in a shorter distance between conductors such as a semiconductor chip, a mounting component, and a conductive pattern, causing electromagnetic field coupling between the conductors, which affects the operating characteristics of the device.

### SUMMARY OF THE INVENTION

In view of the foregoing, it is an object of the present invention to solve the problems of the conventional hybrid integrated circuits and provide a hybrid integrated circuit having high heat dissipation capability and electromagnetic field shielding capability while being compact.

To these ends, according to one aspect of the present invention, there is provided a hybrid integrated circuit comprising a first wiring substrate comprising a plurality of signal line layers and a plurality of ground conductive layers, each of the signal line layers and a corresponding one of the ground conductive layers making up a microstrip line; a cavity formed in the first wiring substrate to expose one of the ground conductive layers at a bottom of the cavity; a semiconductor chip mounted in the cavity and having a bottom surface fixed to the one of the ground conductive layers; and a mounting component mounted to an upper surface of the first wiring substrate but not above the cavity.

Since the hybrid integrated circuit has the semiconductor chip mounted in the cavity and having the bottom surface fixed to the one of the ground conductive layers, it is possible to reduce a distance to transfer heat from the semiconductor chip to a mother board. This allows quick dissipation of the heat generated in the semiconductor chip to the mother board, thus achieving high heat dissipation capability. Further, since the hybrid integrated circuit has the mounting component mounted to the upper surface of the first wiring substrate but not above the cavity, it is possible to suppress the effect of the heat generated in the semiconductor chip on the mounting component. The hybrid integrated circuit may be configured as a matching circuit or a bias circuit, for example.

In a preferred aspect, the hybrid integrated circuit further comprises a second wiring substrate covering the cavity and fixed at least to a top layer of the ground conductive layers of the first wiring substrate. Since the ground conductive layer on the second wiring substrate serves as a shield material, it is possible to reduce electromagnetic coupling of the semiconductor chip with the signal line layers and the mounting component on the first and second wiring substrates, thereby maintaining good operating characteristics of the hybrid integrated circuit. It is also preferred that a ground conductive layer is formed on a substantially entire surface of the second wiring substrate.

In another preferred aspect, another mounting component is mounted to an upper surface or a lower surface of the second wiring substrate. This allows effective use of a space above the cavity to achieve miniaturization of the hybrid integrated circuit. In yet another preferred aspect, another semiconductor chip is mounted to an upper surface of the second wiring substrate. This allows effective use of a space above the cavity to achieve miniaturization of the hybrid integrated circuit and reduction of electromagnetic coupling of the semiconductor chip in the cavity with the another semiconductor chip.

In another preferred aspect, a signal electrode of the semiconductor chip is connected to one of the signal line layers by wire bonding. This allows a large portion of the heat generated by the semiconductor chip to be dissipated to the outside through the bottom surface of the semiconductor chip fixed to the one of the ground conductive layers, thereby further increasing the heat dissipation capability of the hybrid integrated circuit.

In still another preferred aspect, the semiconductor chip is fixed to one of the ground conductive layers of the first wiring substrate by a conductive adhesive. Since the conductor adhesive is highly conductive, it is possible to quickly dissipate the heat generated in the semiconductor chip to the ground conductive layer of the first wiring substrate, thereby further increasing the heat dissipation capability of the hybrid integrated circuit.

Preferably, the hybrid integrated circuit is configured as a high-frequency amplifier circuit. This enables a high-frequency amplifier circuit having good operating characteristics.

In yet another preferred aspect, the first wiring substrate is placed on a mother board.

According to another aspect of the present invention, there is provided a hybrid integrated circuit, comprising a first wiring substrate comprising a plurality of dielectric layers; a cavity formed in a part of a single or a plurality of the plurality of dielectric layers in an upper surface side of the first wiring substrate; a semiconductor chip fixed to a bottom surface of the cavity; and a second wiring substrate covering the cavity. This achieves high heat dissipation capability and good operating characteristics of the hybrid integrated circuit.

In a preferred aspect, a mounting component and/or a semiconductor chip are mounted to an upper surface of the second wiring substrate, and a ground conductive layer is formed on a substantially entire surface of the second wiring substrate.

In a still preferred aspect, the bottom surface of the cavity is on a bottom layer of the dielectric layers of the first wiring substrate, and a mother board is placed in contact with a lower surface of the bottom layer of the dielectric layers.

The above and other objects, features and advantages of the present invention will become more fully understood from the detailed description given hereinbelow and the accompanying drawings which are given by way of illustration only, and thus are not to be considered as limiting the present invention.

### BRIEF DESCRIPTION OF THE DRAWINGS

FIG. 1 is a cross-sectional view showing the structure of a hybrid integrated circuit according to one embodiment of the present invention.

FIGS. 2A and 2B are plan views showing the structure of a second wiring substrate when viewed from above and below, respectively.

FIG. 3 is a cross-sectional view showing the structure of a hybrid integrated circuit according to the first variant embodiment of the present invention.

FIG. 4 is a cross-sectional view showing the structure of a hybrid integrated circuit according to the second variant embodiment of the present invention.

FIG. 5 is a cross-sectional view showing the structure of a hybrid integrated circuit according to the third variant embodiment of the present invention.

FIG. 6 is a cross-sectional view showing the structure of a conventional hybrid integrated circuit.

### DESCRIPTION OF THE PREFERRED EMBODIMENTS

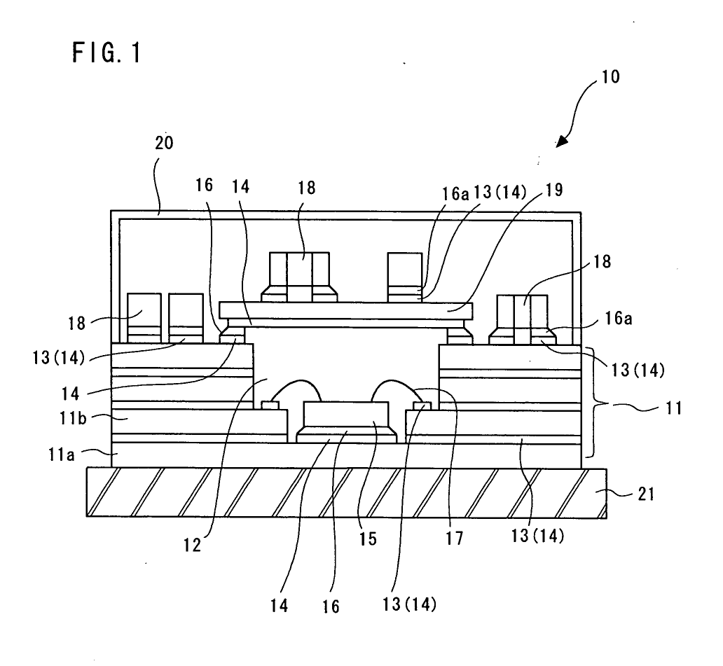

Preferred embodiments of the present invention are explained hereinafter in detail with reference to the drawings. FIG. 1 is a cross-sectional view showing a hybrid integrated circuit according to a specific embodiment of this invention. The hybrid integrated circuit 10 has a first wiring substrate 11 consisting of a lamination of a plurality of dielectric layers 11a, 11b, and so on, placed on a mother board 21. Conductive patterns 13 for signal and Conductive patterns 14 for ground are formed between the dielectric layers constituting the first wiring substrate 11 and above the wiring substrate 11. The signal conductive pattern 13 serves as a signal line layer, and the ground conductive pattern 14 serves as a ground conductive layer. The signal conductive patterns 13 are used for power supply or signal transmission. The signal conductive pattern 13 constitutes a microstrip line together with the ground conductive pattern 14.

The signal conductive patterns 13 and the ground conductive patterns 14 placed between the dielectric layers and above the wiring substrate 11 are vertically connected by an electrode (not shown) formed in a through-hole penetrating the dielectric layers and so on. The signal conductive patterns 13 and the ground conductive patterns 14 may be formed by patterning using etching, for example.

A cavity 12 is formed by removing a part of the upper layers of the plurality of dielectric layers constituting the first wiring substrate 11 to expose the first dielectric layer 11a and the second dielectric layer 11b deposited on the first dielectric layer 11a. The ground conductive pattern 14 is formed on the exposed surface of the first dielectric layer 11a. The signal conductive pattern 13 and the ground conductive pattern 14 are formed on the exposed surface of the second dielectric layer 11b.

A semiconductor chip 15 such as FET is connected to the ground conductive pattern 14 formed on the exposed surface of the first dielectric layer 11a via a conductive adhesive 16 such as a silver paste. The semiconductor chip 15 is a package IC or a bare chip. Terminals of the semiconductor chip 15 are electrically connected to the signal conductive pattern 13 and the ground conductive pattern 14 on the second dielectric layer 11b by a bonding wire 17.

A plurality of mounting components 18 are each connected to the signal conductive pattern 13 and the ground conductive pattern 14 above the first wiring substrate 11 by solder 16a and so on. The mounting components 18 may be a chip capacitor, a chip resistor, a chip inductor, for example. Above the cavity 12, a second wiring substrate 19 consisting of a single dielectric layer is placed to cover the cavity 12.

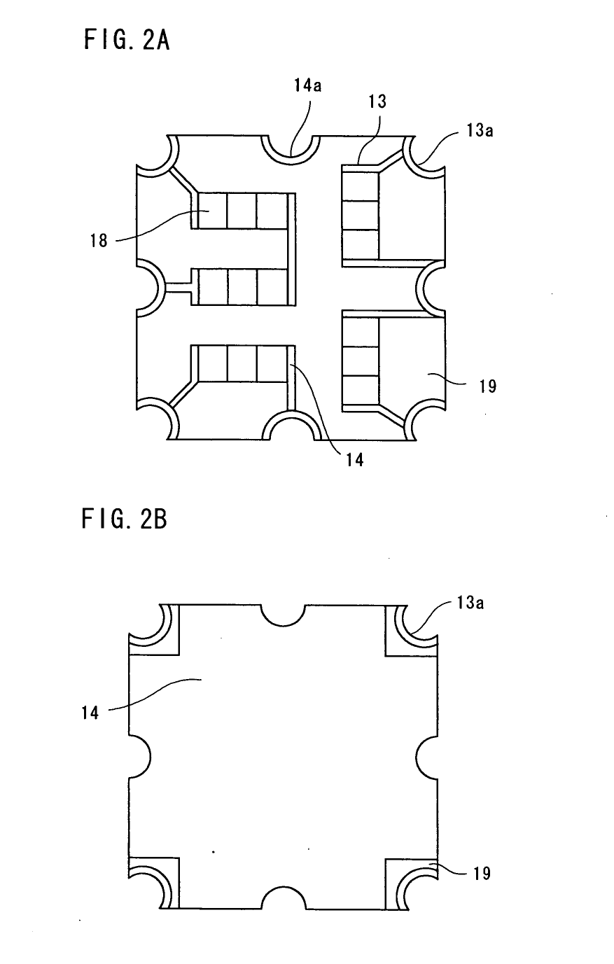

FIGS. 2A and 2B are plan views showing the upper-surface and lower-surface structures, respectively, of the second wiring substrate 19. The second wiring substrate 19 is substantially square. As shown in FIG. 2A, the signal conductive pattern 13 and the ground conductive pattern 14 are placed on the second wiring substrate 19, and a plurality of mounting components 18 are mounted, connected to the signal conductive pattern 13 and the ground conductive pattern 14. Signal electrodes 13a are placed at the four corners of the upper surface and on the side surface adjacent thereto of the second wiring substrate 19, connected to the signal conductive pattern 13. Ground electrodes 14a are placed at the four edges of the upper surface and on the side surface adjacent thereto of the second wiring substrate 19, connected to the ground conductive pattern 14.

On the lower surface of the second wiring substrate 19, as shown in FIG. 2B, the signal electrodes 13a are placed at the four corners, extending from the signal electrodes 13a placed at the four corners of the upper surface and the side surface adjacent thereto of the second wiring substrate 19. The ground conductive pattern 14 is placed on the substantially entire lower surface, except at the four corners, of the second wiring substrate 19, extending from the ground electrodes 14a placed at the four edges of the upper surface and the side surface adjacent thereto of the second wiring substrate 19. The ground electrodes 14a and the signal electrodes 13a may be placed in a through-hole that is created to penetrate the second wiring substrate 19.

The second wiring substrate 19 is placed above the wiring substrate 11 to cover the cavity 12. The signal electrode 13a on the under surface of the second wiring substrate 19 is connected to the signal conductive pattern 13 on the first wiring substrate 11, and the ground conductive pattern 14 on the under surface of the second wiring substrate 19 is connected to the ground conductive pattern 14 on the first wiring substrate 11, each by a conductive adhesive 16 such as solder, silver paste, and so on. The first wiring substrate 11 and the second wiring substrate 19 are covered with a metal case 20. The metal case 20 has an outer side surface which is substantially in plane with the outer side surface of the first wiring substrate 11. The ends of the outer side surface of the case 20 are fixed on the first wiring substrate 11.

The hybrid integrated circuit 10 of this embodiment places the semiconductor chip 15 on the first dielectric layer 11a in the cavity 12, thereby reducing a distance to transfer heat from the semiconductor chip 15 with a high heat value to the mother board 21. It is thus possible to quickly dissipate the heat generated in the semiconductor chip 15 to the mother board 21 below the first wiring substrate 11, allowing the hybrid integrated circuit 10 to have high heat dissipation capability.

In addition, the ground conductive pattern 14 formed substantially entirely on the lower surface of the second wiring substrate 19 serves as a shield plate. It is thus possible to prevent electromagnetic coupling of the semiconductor chip 15 with the signal conductive patterns 13 (microstrip line) and the mounting components 18 on the first and second wiring substrates 11 and 19, thereby improving the operating characteristics of the hybrid integrated circuit 10.

Further, since the signal conductive pattern 13 and the ground conductive pattern 14 are placed on the upper surface of the second wiring substrate 19, electrically connected to the signal conductive pattern 13 and the ground conductive pattern 14 on the under surface of the second wiring substrate 19 by the ground electrode 14a and the signal electrode 13a, respectively, it is possible to further mount a plurality of mounting components 18 to the second wiring substrate 19. This allows effective use of a space above the cavity 12, achieving miniaturization of the hybrid integrated circuit 10. Though, in the hybrid integrated circuit 10 of this embodiment, the second wiring substrate 19 consists of a single dielectric layer, it may consist of a lamination of a plurality of dielectric layers. Further, the semiconductor ship 15 may be covered with a thermosetting resin to be physically protected.

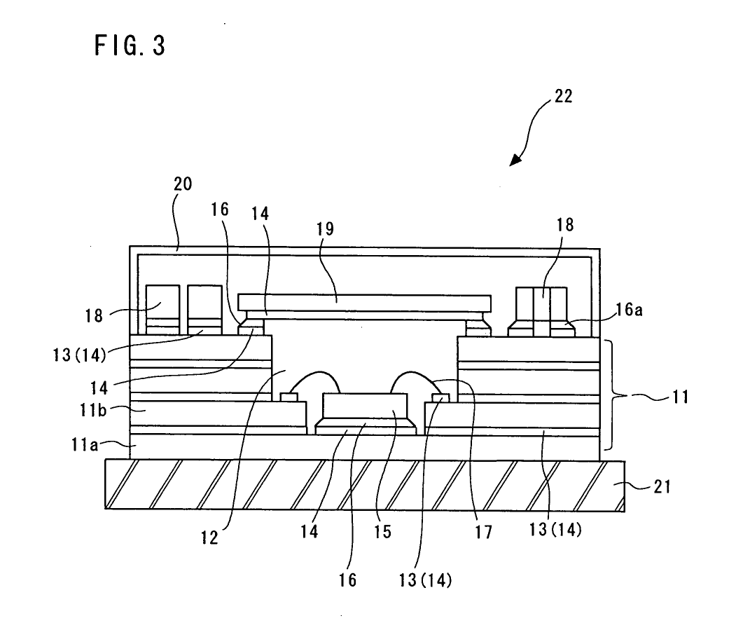

Now, variant embodiments of the present invention are explained hereinafter. FIG. 3 is a cross-sectional view illustrating the structure of a hybrid integrated circuit according to a first variant of the above embodiment. The hybrid integrated circuit 22 has the same structure as the hybrid integrated circuit 10 except that the signal conductive pattern 13, the ground conductive pattern 14, the signal electrode 13a, and the ground electrode 14a are not formed on the upper surface of the second wiring substrate 19, and the plurality of mounting components 18 are not mounted to the upper surface of the second wiring substrate 19.

Since the hybrid integrated circuit 22 of the first variant embodiment does not have the mounting components 18 above the second wiring substrate 19, it has a lower height than the hybrid integrated circuit 10, thus achieving miniaturization.

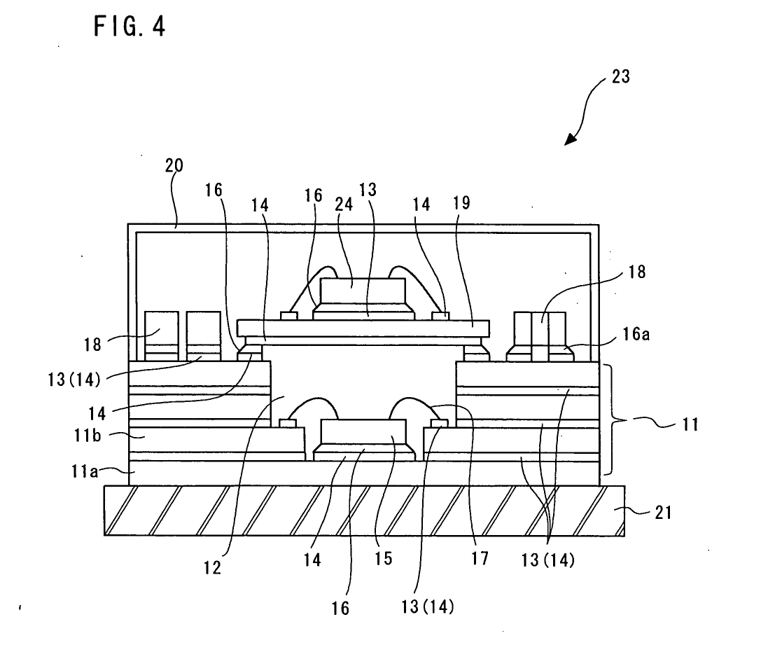

FIG. 4 is a cross-sectional view illustrating the structure of a hybrid integrated circuit according to a second variant of the above embodiment. The hybrid integrated circuit 23 has the same structure as the hybrid integrated circuit 10 except that another semiconductor chip 24, instead of the plurality of mounting components 18, is mounted to the upper surface of the second wiring substrate 19.

The hybrid integrated circuit 23 of the second variant embodiment has the semiconductor chip 24 above the second wiring substrate 19, thus effectively using a space above the cavity 12 to achieve miniaturization of the hybrid integrated circuit. Further, it can suppress electromagnetic coupling between the semiconductor chip 15 in the cavity 12 and the semiconductor chip 24 placed above the second wiring substrate 19.

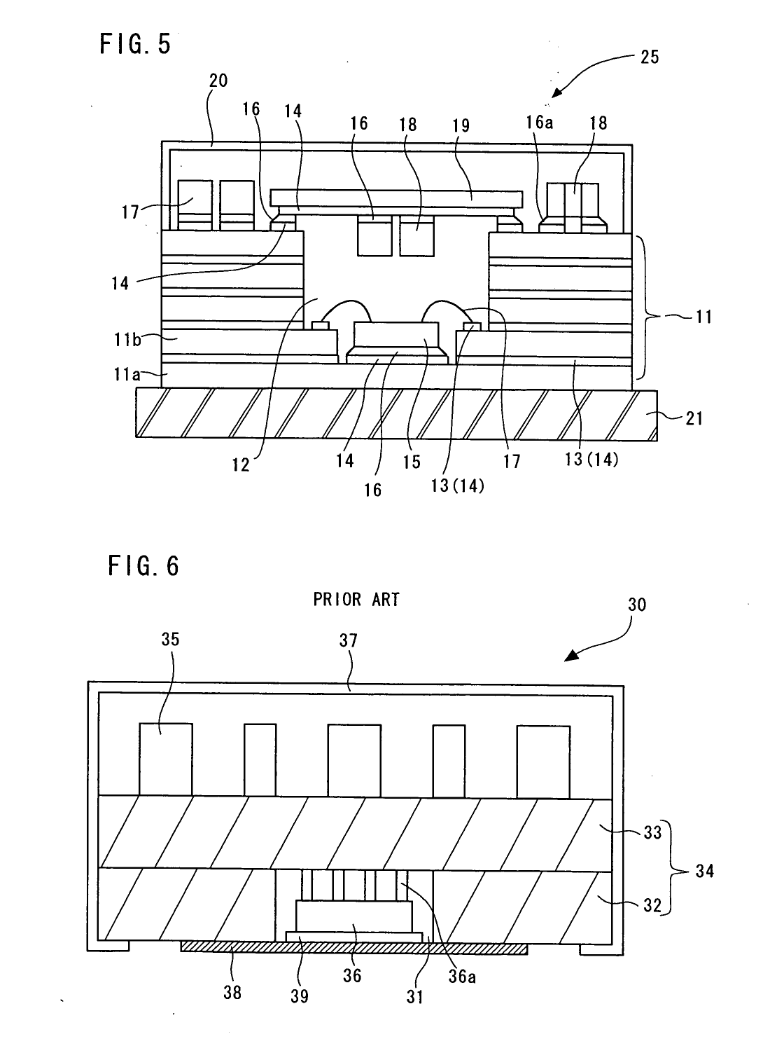

FIG. 5 is a cross-sectional view illustrating the structure of a hybrid integrated circuit according to a third variant of the above embodiment. In the hybrid integrated circuit 25, the signal conductive pattern 13, the ground conductive pattern 14, the signal electrode 13a, and the ground electrode 14a are not formed on the upper surface of the second wiring substrate 19, and the plurality of mounting components 18 are also not mounted to the upper surface of the second wiring substrate 19. Instead, the signal conductive pattern 13 and the ground conductive pattern 14 are formed on the lower surface of the second wiring substrate 19, and a plurality of mounting components 18 are connected to the signal conductive pattern 13 and the ground conductive pattern 14 by solder 16a and so on. The hybrid integrated circuit 25 of this variant embodiment has the same structure as the hybrid integrated circuit 10 of the above embodiment except for the above.

The hybrid integrated circuit 25 of this variant embodiment has the plurality of mounting components 18 below the lower surface of the wiring substrate 19, thus effectively using a space above the cavity 12. It is thus possible to lower the height of the device and achieve miniaturization of the hybrid integrated circuit. In the hybrid integrated circuit 25 of this variant embodiment, another semiconductor chip 24 may be mounted instead of the mounting components 18; further, both the mounting components 18 and the semiconductor chip 24 may be mounted.

Though the present embodiment has been explained above in conjunction with the preferred embodiments, the hybrid integrated circuit of this invention is not limited to the structure described in the above embodiments, and hybrid integrated circuits in which various alterations and modifications are made to the above embodiments are within the scope of the invention. For example, it is possible to mount the mounting components 18 and the semiconductor chip 24 to the upper surface of the second wiring substrate 19 and further mount the mounting components 18 and the semiconductor chip 24 to the lower surface of the second wiring substrate 19.

As described in the foregoing, in the hybrid integrated circuit of this invention, since the semiconductor chip is placed in the cavity, with its bottom surface fixed on one ground conductive layer, the distance to transfer heat from the semiconductor chip to the mother board can be reduced. This allows quick dissipation of the heat generated in the semiconductor chip to the mother board, thus improving the heat dissipation capability. Further, since the mounting components are mounted to the upper surface of the first wiring substrate but not above the cavity, an effect of the heat generated in the semiconductor chip on the mounting components may be suppressed.

From the invention thus described, it will be obvious that the embodiments of the invention may be varied in many ways. Such variations are not to be regarded as a departure from the spirit and scope of the invention, and all such modifications as would be obvious to one skilled in the art are intended for inclusion within the scope of the following claims.

1. A hybrid integrated circuit comprising:
a first wiring substrate comprising a plurality of signal line layers and a plurality of ground conductive layers, each of the signal line layers and a corresponding one of the ground conductive layers making up a microstrip line;
a cavity formed in the first wiring substrate to expose one of the ground conductive layers at a bottom of the cavity;
a semiconductor chip mounted in the cavity and having a bottom surface fixed to the one of the ground conductive layers; and
a mounting component mounted to an upper surface of the first wiring substrate but not above the cavity.

2. A hybrid integrated circuit according to claim 1, further comprising a second wiring substrate covering the cavity and fixed at least to a top layer of the ground conductive layers of the first wiring substrate.

3. A hybrid integrated circuit according to claim 2, wherein a ground conductive layer is formed on a substantially entire surface of the second wiring substrate.

4. A hybrid integrated circuit according to claim 2, wherein another mounting component is mounted to an upper surface or a lower surface of the second wiring substrate.

5. A hybrid integrated circuit according to claim 2, wherein another semiconductor chip is mounted to an upper surface of the second wiring substrate.

6. A hybrid integrated circuit according to claim 1, wherein a signal electrode of the semiconductor chip is connected to one of the signal line layers by wire bonding.

7. A hybrid integrated circuit according to claim 1, wherein the semiconductor chip is fixed to one of the ground conductive layers of the first wiring substrate by a conductive adhesive.

8. A hybrid integrated circuit according to claim 1, configured as a high-frequency amplifier circuit.

9. A hybrid integrated circuit according to claim 1, wherein the first wiring substrate is placed on a mother board.

10. A hybrid integrated circuit, comprising:
a first wiring substrate comprising a plurality of dielectric layers;
a cavity formed in a part of a single or a plurality of the plurality of dielectric layers in an upper surface side of the first wiring substrate;
a semiconductor chip fixed to a bottom surface of the cavity; and
a second wiring substrate covering the cavity.

11. A hybrid integrated circuit according to claim 10, wherein a mounting component and/or a semiconductor chip are mounted to an upper surface of the second wiring substrate, and a ground conductive layer is formed on a substantially entire surface of the second wiring substrate.

12. A hybrid integrated circuit according to claim 10, wherein the bottom surface of the cavity is on a bottom layer of the dielectric layers of the first wiring substrate, and a mother board is placed in contact with a lower surface of the bottom layer of the dielectric layers.
